(19) United States
(12) Patent Application Publication
(10) Pub. No.: US 2024/0165758 A1
(43) Pub. Date: May 23, 2024

(54) PROCESSING SUBSTRATE APPARATUS AND METHOD

(71) Applicant: SEMES CO., LTD., Cheonan-si (KR)

(72) Inventors: Jeong Yeong PARK, Cheonan-si (KR); Seong Soo LEE, Cheonan-si (KR)

(73) Assignee: SEMES CO., LTD., Cheonan-si (KR)

(21) Appl. No.: 18/485,701

(22) Filed: Oct. 12, 2023

(30) Foreign Application Priority Data
Nov. 22, 2022 (KR) 10-2022-0157848

(51) Int. Cl. B23Q 3/06; B23Q 3/10

(52) U.S. Cl. CPC B23Q 3/062; B23Q 3/107

(57) ABSTRACT

Disclosed are a substrate processing apparatus and a substrate processing method capable of improving processing uniformity of a substrate. The substrate processing apparatus includes a body configured to spin-rotate; a plurality of support pins installed on the body so as to support the substrate thereon; a plurality of chuck pins installed on the body so as to grip a side surface of the substrate; a chuck pin driver device configured to move the chuck pin from a stand-by position to a grip position when the substrate has been seated on the support pin; and a support pin spacing device configured to space the substrate and at least one of the support pins from each other while the chuck pin is gripping the substrate.

### CROSS-REFERENCE TO RELATED PATENT APPLICATION

This application claims priority to and the benefit of Korean Patent Application No. 10-2022-0157848, filed on Nov. 22, 2022, the disclosure of which is incorporated herein by reference in its entirety.

### BACKGROUND OF THE INVENTION

### 1. Field of the Invention

The present disclosure relates to a substrate processing apparatus and a substrate processing method, and more particularly, to a substrate processing apparatus and a substrate processing method in which a substrate is processed at an improved uniformity.

### 2. Description of the Related Art

In general, a semiconductor process may include various processes such as forming or etching a thin film on a wafer and cleaning generated foreign substances, particles, and process by-products. Such a process may be performed by placing the wafer on a spin head such that a pattern surface of the wafer faces upwards or downwards, and rotating the spin head at high speed while supplying treatment liquid to the wafer.

In this spin head, a plurality of support pins supporting a lower surface of the wafer may be fixedly installed on a head body. Chuck pins supporting a side surface of the wafer may be installed between the fixed support pins so as to prevent the wafer from being removed from the head body during spin-rotation of the wafer.

In this regard, when the wafer has been seated on the support pins by a chuck pin driver device, the chuck pins may be displaced from a stand-by position to a gripping position to firmly grip the wafer.

However, the conventional spin chuck device equipped with the fixed support pins has a configuration in which the support pins are always in contact with the substrate while the process such as etching or cleaning is in progress or during the spin-rotation thereof. Thus, the etching liquid or cleaning liquid does not sufficiently invade a contact portion between the support pins and the substrate such that the contact portion is not sufficiently etched or sufficiently cleaned, resulting in process non-uniformity. This may adversely affect a subsequent process and or lower the process uniformity, thereby causing occurrence of various process issues.

### SUMMARY OF THE INVENTION

The present disclosure is intended to solve various problems including the above problems. A purpose of the present disclosure is to provide a substrate processing apparatus and substrate processing method that may space the substrate and all support pins from each other or space the substrate and some of the support pins from each other during a process, thereby greatly improving the process uniformity of a back side of the substrate.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A first aspect of the present disclosure provides a substrate processing apparatus comprising: a body configured to spin-rotate; a plurality of support pins installed on the body so as to support the substrate thereon; a plurality of chuck pins installed on the body so as to grip a side surface of the substrate; a chuck pin driver device configured to move the chuck pin from a stand-by position to a grip position when the substrate has been seated on the support pin; and a support pin spacing device configured to space the substrate and at least one of the support pins from each other while the chuck pin is gripping the substrate.

In one implementation of the substrate processing apparatus, the support pin spacing device includes: a support pin elevating and lowering device configured to lower the at least one support pin such that a vertical level of a top of the at least one support pin is lower than a vertical level of a top of the chuck pin; and a controller configured to apply a lowering control signal to the support pin elevating and lowering device based on a type of a process.

In one implementation of the substrate processing apparatus, the support pin elevating and lowering device includes: a support pin moving table configured to support and move the at least one support pin to elevate or lower the at least one support pin while passing through an upper plate of the body; and a support pin elevating and lowering driver device configured to elevate and lower the support pin moving table.

In one implementation of the substrate processing apparatus, when the chuck pin grips the substrate, the support pin elevating and lowering device is configured to lower all the support pins relative to the chuck pin.

In one implementation of the substrate processing apparatus, when the chuck pin grips the substrate, the support pin elevating and lowering device is configured to bring at least one support pin into contact with the substrate and to lower at least one further support pin relative to the chuck pin.

In one implementation of the substrate processing apparatus, in a top view of the body, the chuck pins are respectively positioned at 2 o'clock, 4 o'clock, 6 o'clock, 8 o'clock, 10 o'clock, and 12 o'clock positions, wherein the support pins are respectively positioned at 1 o'clock, 3 o'clock, 5 o'clock, 7 o'clock, 9 o'clock, and 11 o'clock positions, wherein the support pin elevating and lowering device is configured to bring the support pins respectively positioned at the 3 o'clock, 7 o'clock and 11 o'clock positions into contact with the substrate, and to lower the support pins respectively positioned at the 1 o'clock, 5 o'clock, and 9 o'clock positions so as to be spaced from the substrate.

In one implementation of the substrate processing apparatus, in a top view of the body, the chuck pins are respectively positioned at 2 o'clock, 4 o'clock, 6 o'clock, 8 o'clock, 10 o'clock, and 12 o'clock positions, wherein the support pins are respectively positioned at 1 o'clock, 3 o'clock, 5 o'clock, 7 o'clock, 9 o'clock, and 11 o'clock positions, wherein the support pin elevating and lowering device is configured to: for a first process time, bring the support pins respectively positioned at the 3 o'clock, 7 o'clock and 11 o'clock positions into contact with the substrate, and to lower the support pins respectively positioned at the 1 o'clock, 5 o'clock, and 9 o'clock positions so as to be spaced from the substrate; and for a second process time, bring the support pins respectively positioned at the 1 o'clock, 5 o'clock, and 9 o'clock positions into contact with the substrate, and to lower the support pins respectively positioned at the 3 o'clock, 7 o'clock and 11 o'clock positions so as to be spaced from the substrate.

In one implementation of the substrate processing apparatus, the support pin moving table is embodied as a support pin moving plate for supporting the plurality of the support pins, wherein the support pin elevating and lowering driver device is embodied as a support pin moving plate cylinder or a support pin moving plate actuator for elevating and lowering the support pin moving plate.

In one implementation of the substrate processing apparatus, the support pin moving table includes an elevating and lowering cam pin formed at a lower end of the support pin so as to protrude therefrom, wherein the support pin elevating and lowering driver device includes an elevating and lowering cam member having a cam hole defined therein extending in a bent manner, wherein at least a portion of the elevating and lowering cam pin is inserted in the cam hole such that the cam hole allows the elevating and lowering cam pin to move upwardly or downwardly.

In one implementation of the substrate processing apparatus, the chuck pin driver device includes: a movable rod connected to the chuck pin and linearly displaced by a linear movement guide; an elastic member providing an elastic restoring force in a direction in which the movable rod moves forwards; and a rotatable cam member having a protrusion formed on one side of an outer circumferential surface of the rotatable cam member, wherein the protrusion faces the movable rod and is capable of pressing the movable rod so as to move the movable rod backwards, based on a rotation angle by which the rotatable cam member is rotated by a cam driver, wherein the elevating and lowering cam member is installed on an extension formed on the other side of the outer circumferential surface of the rotatable cam member, and thus is associated with the chuck pin driver device so as to elevate and lower the elevating and lowering cam pin based on the rotation angle by which the rotatable cam member rotates.

In one implementation of the substrate processing apparatus, the elevating and lowering cam member includes: an outer cam portion having a cam hole defined therein receiving therein an elevating and lowering cam pin disposed at a lower end of the support pin and protruding therefrom outwardly; and an inner cam portion connected to a rear end of the outer cam portion via a connection portion, wherein the cam hole receiving therein the elevating and lowering cam pin disposed at the lower end of the support pin and protruding therefrom outwardly is defined in the inner cam portion, wherein the extension is connected to the connection portion.

In one implementation of the substrate processing apparatus, each of the outer cam portion and the inner cam portion is generally formed in a partial arc shape such that a spacing between each of the outer cam portion and the inner cam portion and the outer circumferential surface of the rotatable cam member is constant along the outer circumferential surface thereof.

In one implementation of the substrate processing apparatus, the support pin spacing device includes: a chuck pin elevating and lowering device configured to elevate the chuck pin relative to the support pin such that a vertical level of a top of the chuck pin is higher than a vertical level of a top of the support pin; and a controller configured to apply an elevating control signal to the chuck pin elevating and lowering device based on a type of a process.

In one implementation of the substrate processing apparatus, the chuck pin elevating and lowering device includes: a chuck pin moving table configured to support and move a plurality of chuck pins to elevate or lower the plurality of chuck pins while passing through an upper plate of the body; and a chuck pin elevating and lowering driver device configured to elevate or lower the chuck pin moving table.

In one implementation of the substrate processing apparatus, the chuck pin moving table is embodied as a chuck pin moving plate supporting the plurality of chuck pins, wherein the chuck pin elevating and lowering driver device is embodied as a chuck pin moving plate cylinder or a chuck pin moving plate actuator configured to elevate or lower the chuck pin moving plate.

A second aspect of the present disclosure provides a substrate processing method comprising: (a) seating a substrate on a plurality of support pins installed on a body; (b) moving, by a chuck pin driver device, a plurality of chuck pins installed on the body from a stand-by position to a gripping position to grip a side surface of the substrate; and (c) spacing the substrate and at least one of the support pins from each other while the chuck pin grips the substrate.

In one implementation of the method, the (c) includes spacing the substrate and the at least one of the support pins from each other using a support pin elevating and lowering device or a chuck pin elevating and lowering device during a process or before the process, wherein the process is one selected from: a pre-rinse process of rotating the substrate at a first rotation speed while supplying a pre-rinse liquid to the substrate; an initial etching process of rotating the substrate at a second rotation speed while supplying an etchant to a center of the substrate; a middle etching process of rotating the substrate at a third rotation speed while supplying an etchant to the substrate in a scanning manner; a last etching process of stopping the supply of the etchant to the substrate, and rotating the substrate at a fourth rotation speed to remove the etchant remaining on the substrate; a cleaning process of rotating the substrate at a fifth rotation speed while supplying a rinse liquid or cleaning liquid to the substrate so as to clean the substrate; a drying process of supplying a drying gas to the substrate or rotating the substrate at a sixth rotation speed in a dried state thereof; and combinations thereof.

In one implementation of the method, the (c) includes determining a number of the support pins to be spaced from the substrate or a position of the support pin to be spaced from the substrate, based on the rotation speed of the substrate.

In one implementation of the method, the (c) includes: when in a top view of the body, the chuck pins are respectively positioned at 2 o'clock, 4 o'clock, 6 o'clock, 8 o'clock, 10 o'clock, and 12 o'clock positions, and the support pins are respectively positioned at 1 o'clock, 3 o'clock, 5 o'clock, 7 o'clock, 9 o'clock, and 11 o'clock positions, brining, by a support pin elevating and lowering device, the support pins respectively positioned at the 3 o'clock, 7 o'clock and 11 o'clock positions into contact with the substrate, and lowering, by the support pin elevating and lowering device, the support pins respectively positioned at the 1 o'clock, 5 o'clock, and 9 o'clock positions so as to be spaced from the substrate; or for a first process time, bringing, by the support pin elevating and lowering device, the support pins respectively positioned at the 3 o'clock, 7 o'clock and 11 o'clock positions into contact with the substrate, and lowering, by the support pin elevating and lowering device, the support pins respectively positioned at the 1 o'clock, 5 o'clock, and 9 o'clock positions so as to be spaced from the substrate; and then, for a second process time, bringing, by the support pin elevating and lowering device, the support pins respectively positioned at the 1 o'clock, 5 o'clock, and 9 o'clock positions into contact with the substrate, and lowering, by the support pin elevating and lowering device, the support pins respectively positioned at the 3 o'clock, 7 o'clock and 11 o'clock positions so as to be spaced from the substrate.

A third aspect of the present disclosure provides a substrate processing apparatus comprising: a body configured to spin-rotate; a plurality of support pins installed on the body so as to support the substrate thereon; a plurality of chuck pins installed on the body so as to grip a side surface of the substrate; a chuck pin driver device configured to move the chuck pin from a stand-by position to a grip position when the substrate has been seated on the support pin; and a support pin spacing device configured to space the substrate and at least one of the support pins from each other while the chuck pin is gripping the substrate, wherein the support pin spacing device includes: a support pin elevating and lowering device configured to lower the at least one support pin such that a vertical level of a top of the at least one support pin is lower than a vertical level of a top of the chuck pin; and a controller configured to apply a lowering control signal to the support pin elevating and lowering device based on a type of a process, wherein the support pin elevating and lowering device includes: a support pin moving table configured to support and move the at least one support pin to elevate or lower the at least one support pin while passing through an upper plate of the body; and a support pin elevating and lowering driver device configured to elevate and lower the support pin moving table, wherein the support pin moving table includes an elevating and lowering cam pin formed at a lower end of the support pin so as to protrude therefrom, wherein the support pin elevating and lowering driver device includes an elevating and lowering cam member having a cam hole defined therein extending in a bent manner, wherein at least a portion of the elevating and lowering cam pin is inserted in the cam hole such that the cam hole allows the elevating and lowering cam pin to move upwardly or downwardly, wherein the chuck pin driver device includes: a movable rod connected to the chuck pin and linearly displaced by a linear movement guide; an elastic member providing an clastic restoring force in a direction in which the movable rod moves forwards; and a rotatable cam member having a protrusion formed on one side of an outer circumferential surface of the rotatable cam member, wherein the protrusion faces the movable rod and is capable of pressing the movable rod so as to move the movable rod backwards, based on a rotation angle by which the rotatable cam member is rotated by a cam driver, wherein the elevating and lowering cam member is installed on an extension formed on the other side of the outer circumferential surface of the rotatable cam member, and thus is associated with the chuck pin driver device so as to elevate and lower the elevating and lowering cam pin based on the rotation angle by which the rotatable cam member rotates, wherein the elevating and lowering cam member includes: an outer cam portion having a cam hole defined therein receiving therein an elevating and lowering cam pin disposed at a lower end of the support pin and protruding therefrom outwardly; and an inner cam portion connected to a rear end of the outer cam portion via a connection portion, wherein the cam hole receiving therein the elevating and lowering cam pin disposed at the lower end of the support pin and protruding therefrom outwardly is defined in the inner cam portion, wherein the extension is connected to the connection portion, wherein each of the outer cam portion and the inner cam portion is generally formed in a partial arc shape such that a spacing between each of the outer cam portion and the inner cam portion and the outer circumferential surface of the rotatable cam member is constant along the outer circumferential surface thereof.

According to the various aspects and implantations of the present disclosure as described above, the process uniformity of the back surface of the substrate may be greatly improved by spacing the substrate and all support pins from each other or spacing the substrate and some support pins from each other during the process. As a result, a subsequent process may smoothly proceed, and a high-quality product with high yield and reliability may be produced. In addition to the above effects, specific effects of the present disclosure are described together while describing specific details for carrying out the present disclosure. Effects of the present disclosure are not limited to the effects mentioned above, and other effects not mentioned will be clearly understood by those skilled in the art from the descriptions below.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a plan view illustrating a substrate processing apparatus according to some embodiments of the present disclosure;

FIG. 2 is a cross-sectional view showing the substrate processing apparatus of FIG. 1;

FIG. 3 is a partially cut perspective view showing the substrate processing apparatus of FIG. 1;

FIG. 4 is a plan view showing the substrate processing apparatus of FIG. 1;

FIG. 5 is a side elevation view showing the substrate processing apparatus of FIG. 4;

FIG. 6 is a conceptual diagram showing an example of a support pin elevating and lowering device of the substrate processing apparatus of FIG. 5;

FIG. 7 is a cross-sectional view showing a support pin lowered state according to another example of the support pin elevating and lowering device of the substrate processing apparatus of FIG. 5;

FIG. 8 is a cross-sectional view showing a support pin elevated state of the support pin elevating and lowering device of the substrate processing apparatus in FIG. 7;

FIG. 9 is a plan view showing the support pin elevating and lowering device of the substrate processing apparatus of FIG. 8;

FIG. 10 is a perspective view showing the support pin elevating and lowering device of the substrate processing apparatus of FIG. 9;

FIG. 11 is a plan view showing the substrate processing apparatus of FIG. 9;

FIG. 12 is a cross-sectional view showing the substrate processing apparatus of FIG. 11;

FIGS. 13 to 15 are partially enlarged plan views showing an operation process of the substrate processing apparatus of FIG. 11 step by step;

FIG. 16 is a conceptual diagram showing a substrate seated state according to another example of the chuck pin elevating and lowering device of the substrate processing apparatus of FIG. 5;

FIG. 17 is a conceptual diagram showing a substrate griping state according to the chuck pin elevating and lowering device of the substrate processing apparatus of FIG. 16;

FIG. 18 is a conceptual diagram showing a substrate elevated state according to the chuck pin elevating and lowering device of the substrate processing apparatus of FIG. 17;

FIG. 19 is a plan view showing a substrate processing facility where the substrate processing apparatus of FIGS. 1 to 18 is installed; and

FIG. 20 is a flowchart illustrating a substrate processing method according to some embodiments of the present disclosure.

### DETAILED DESCRIPTION OF THE INVENTION

Hereinafter, several preferred embodiments of the present disclosure will be described in detail with reference to the accompanying drawings.

The embodiments of the present disclosure are provided to more completely describe the present disclosure for those skilled in the art. The following embodiments may be modified in various forms, and the scope of the present disclosure is not limited to the following embodiments. Rather, these embodiments are provided so that the present disclosure is thorough and complete, and are provided to fully convey the spirit of the present disclosure to those skilled in the art. Furthermore, a thickness or a size of each layer in the drawing is exaggerated for convenience and clarity of illustration. A shape, a size, a ratio, an angle, a number, etc. disclosed in the drawings for describing embodiments of the present disclosure are illustrative, and the present disclosure is not limited thereto. The same reference numerals refer to the same elements herein.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

Hereinafter, embodiments of the present disclosure will be described with reference to drawings schematically showing ideal embodiments of the present disclosure. In the drawings, variations of a depicted shape may be expected, depending, for example, on manufacturing techniques and/or tolerances. Therefore, the embodiments of the present disclosure should not be construed as being limited to the specific shape of the area shown herein, and should include, for example, change in a shape caused in a manufacturing process.

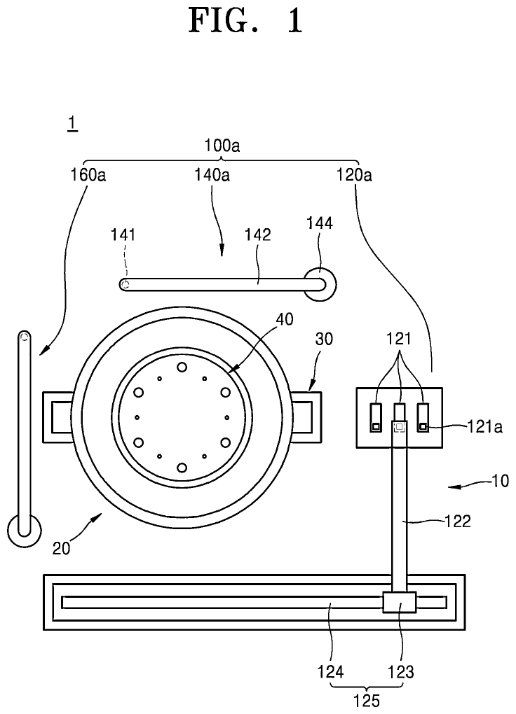

FIG. 1 is a plan view illustrating a substrate processing apparatus 1 according to some embodiments of the present disclosure.

Referring to FIG. 1, the substrate processing apparatus 1 may include a fluid supply unit 10, a container 20, a lift unit 30, and a spin chuck device 40.

The fluid supply unit 10 may supply treatment liquid or treatment gas for substrate treatment to a substrate W. The spin chuck device 40 supports the substrate W during the process and may rotate the substrate W. The container 20 may prevent chemicals used in the process and fumes generated during the process from splashing or leaking to the outside. The lift unit 30 may move the spin chuck device 40 or the container 20 up and down, and may change a relative vertical distance between the container 20 and the spin chuck device 40 in the container 20.

The fluid supply unit 10 has an upper nozzle member 100a and a lower nozzle member 100b. The upper nozzle member 100a may supply the treatment liquid or treatment gas to an upper surface of the substrate W placed on the spin chuck device 40, and the lower nozzle member 100b supply the treatment liquid or treatment gas to a lower surface of the substrate W placed on the spin chuck device 40. The substrate W is placed on the spin chuck device 40 so as to be spaced, by a certain distance, from an upper surface of the spin chuck device 40. The lower nozzle member 100b may supply the treatment liquid or treatment gas to a space between the spin chuck device 40 and the substrate W.

The upper nozzle member 100a may include a chemical supply nozzle 120a, a rinse liquid supply nozzle 140a, and a drying gas supply nozzle 160a. The chemical supply nozzle 120a may supply a plurality of types of chemicals to the substrate W. The chemical supply nozzle 120a may include a plurality of ejectors 121, a support bar 122, and a bar mover 125. The ejectors 121 are disposed on one side of the container 20. The ejector 121 may be connected to chemical storage (not shown) and may receive chemical from the chemical storage. The ejectors 121 may be respectively connected to chemical storages that store therein different types of chemicals, respectively. The ejectors 121 may be arranged side by side in one direction. Each ejector 121 has a protrusion 121a protruding upwardly, and a groove (not shown) may be formed in a side surface of the protrusion 121a. The chemical may be sulfuric acid, nitric acid, ammonia, hydrofluoric acid, etc., or a mixture thereof with deionized water. A discharge hole may be formed at an end of each ejector 121.

The support bar 122 may be coupled to one of the plurality of ejectors 121 and move one ejector coupled thereto to a position on top of the substrate W placed on the spin chuck device 40. The support bar 122 has an elongate rod shape, and a length direction of the support bar 122 may be perpendicular to a direction in which the ejectors 121 are arranged. A holder (not shown) for coupling the support bar 122 to the ejector 121 is provided on a lower surface of the support bar 122. The holder may include arms (not shown) that can be inserted into the groove formed in the protrusion 121a of the ejector 121. The arm may be provided in a structure in which the arm may be rotatable or displaced in a direction from an outside of the protrusion 121a toward the groove of the protrusion 121a.

The bar mover 125 may linearly move the support bar 122 between a position on top of the substrate W placed on the spin chuck device 40 and a position on top of the ejectors 121. The bar mover 125 may include a bracket 123, a guide rail 124, and a driver (not shown). The guide rail 124 may extend in a long straight line from an outside of the ejectors 121 through the ejector 121 and the container 20 to an outside of the container 20. The bracket 123 may be coupled to the guide rail 124 so as to be movable along the guide rail, and the support bar 122 may be fixedly coupled to the bracket 123. The driver may provide a driving force to linearly move the bracket 123. The linear movement of the bracket 123 may be achieved by an assembly having a motor and a screw. Alternatively, the linear movement of the bracket 123 may be achieved by an assembly of a belt, a pulley, and a motor. Alternatively, the linear movement of the bracket 123 may be achieved by a linear motor.

The rinse liquid supply nozzle 140a may be disposed on another side of the container 20, and the drying gas supply nozzle 160a may be disposed on still another side of the container 20. The rinse liquid supply nozzle 140a may include an ejector 141, a support bar 142, and a driver 144. The ejector 141 may be fixedly coupled to one end of the support bar 142. A rotatable shaft (not shown) rotated by the driver 144 may be fixedly coupled to the other end of the support bar 142. The ejector 141 may receive the rinse liquid from rinse liquid storage (not shown). The drying gas supply nozzle 160a may have a structure substantially similar to that of the rinse liquid supply nozzle 140a. The drying gas supply nozzle 160a may supply isopropyl alcohol vapor and nitrogen gas. In this regard, the nitrogen gas may be heated nitrogen gas.

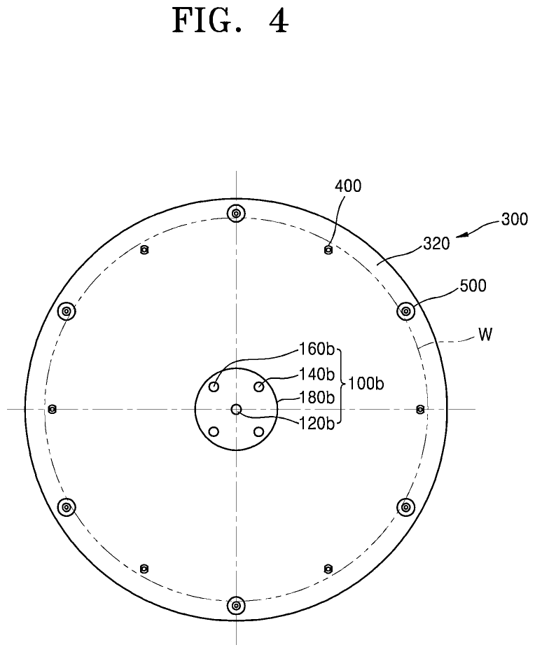

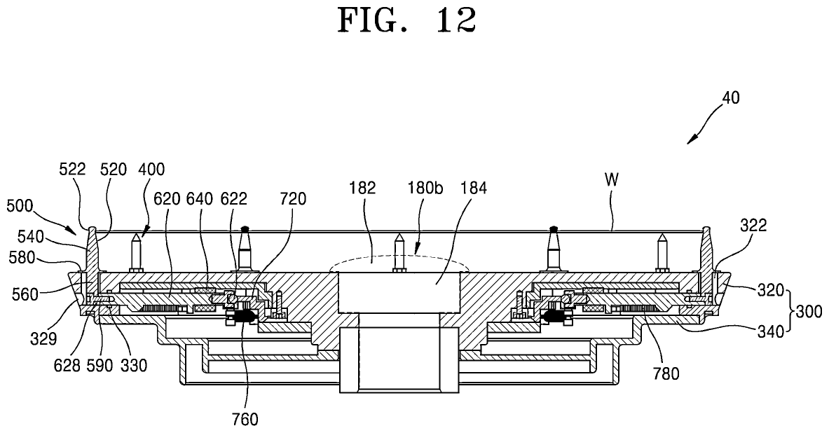

The lower nozzle member 100b has an ejection head (180b in FIG. 4). The ejection head 180b has a head portion (182 in FIG. 12) and an insert portion (184 in FIG. 12). The head portion 182 has an upwardly convex shape and may protrude upwards from the spin chuck device 40. A plurality of discharge holes are formed in the head portion 182. The discharge holes may respectively dispense one of the various types of chemicals, the rinse liquid, and the drying gas such as the isopropyl alcohol vapor or the nitrogen gas. The insert portion 184 has a diameter which is constant in a longitudinal direction, and which is smaller than a lower end of the head portion 182. The insert portion 184 may extend downwards from the head portion 182. The insert portion 184 may be inserted into a through hole formed in a center of the spin chuck device 40.

The chemical, the rinse liquid, and the drying gas supplied from the upper nozzle member 100a and the lower nozzle member 100b may be spread from a central area of the upper or lower surface of the substrate W to an edge area thereof under the spin-rotation of the spin chuck device 40, and thus may clean the substrate W.

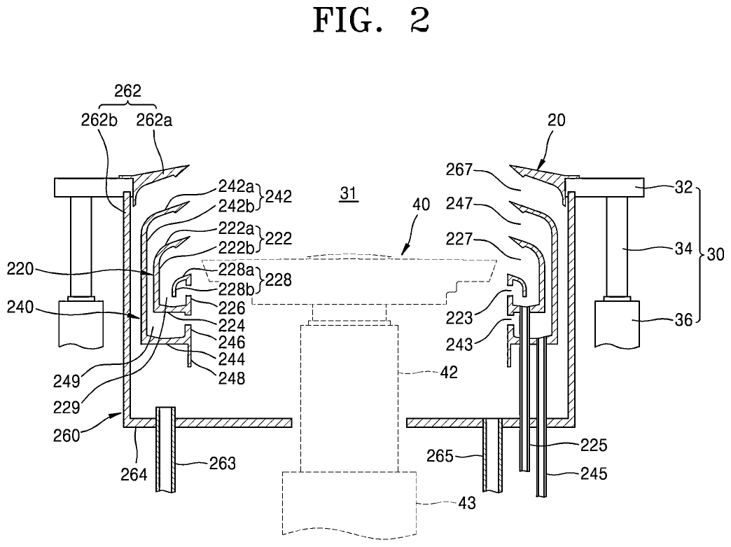

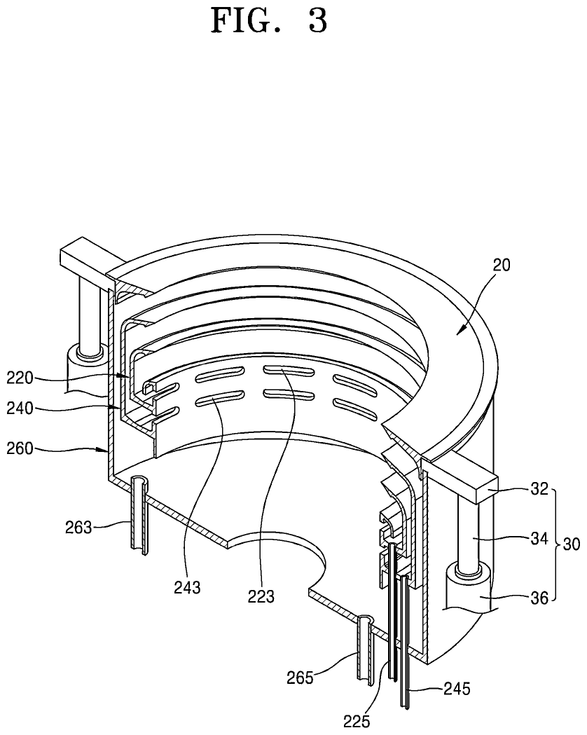

FIG. 2 is a cross-sectional view showing the container 20 of the substrate processing apparatus 1 in FIG. 1. FIG. 3 is a partially cut perspective view of FIG. 2.

Referring to FIG. 2 and FIG. 3, the container 20 has an open top and has an inner space 31 defined therein in which the substrate W is processed. The spin chuck device 40 may be placed in the inner space 31. A rotatable shaft 42 supporting and rotating the spin chuck device 40 may be fixedly coupled to a lower surface of the spin chuck device 40. The rotatable shaft 42 may extend through an opening formed in a bottom surface of the container 20 and out of the container 20. The driver 44 such as a motor providing a rotational force may be fixedly coupled to the rotatable shaft 42.

The container 20 may have a structure capable of separating and collecting the chemicals used in the process. This allows reuse of the chemicals. The container 20 has a plurality of collection containers 220, 240, and 260. The collection containers 220, 240, and 260 respectively collect different types of treatment liquids as used in the process. According to some embodiments of the present disclosure, the container 20 may have three collection containers. The three collection containers may be respectively referred to as an inner collection container 220, a middle collection container 240, and an outer collection container 260.

The inner collection container 220 may be provided in an annular ring shape surrounding the spin chuck device 40. The middle collection container 240 may be provided in an annular ring shape surrounding the inner collection container 220. The outer collection container 260 may be provided in an annular ring shape surrounding the middle collection container 240. Inlets 227, 247, and 267 communicating with the inner space 31 of the container 20 may be respectively formed in the collection containers 220, 240, and 260. Each of the inlets 227, 247, and 267 may be provided in a ring shape around the spin chuck device 40.

The chemicals which have been sprayed onto the substrate W and have been used in the process may respectively flow into the collection containers 220, 240, and 260 through the inlets 227, 247, and 267 under a centrifugal force caused by the spin-rotation of the substrate W. The inlet 267 of the outer collection container 260 may be provided vertically above the inlet 247 of the middle collection container 240. The inlet 247 of the middle collection container 240 may be provided vertically above the inlet 227 of the inner collection container 220.

That is, the inlets 227, 247, and 267 of the inner collection container 220, the middle collection container 240, and the outer collection container 260 may be positioned at different vertical levels.

The inner collection container 220 may have an outer wall 222, a bottom wall 224, an inner wall 226, and a guide wall 228. Each of the outer wall 222, the bottom wall 224, the inner wall 226, and the guide wall 228 may have a ring shape. The outer wall 222 has an inclined wall 222a that extends inclinedly downwardly so as to extend away from the spin chuck device 40 and a vertical wall 222b that extends vertically downwardly from a lower end of the inclined wall 222a. The bottom wall 224 may extend horizontally from a lower end of the vertical wall 222b toward the spin chuck device 40. The bottom wall 224 may extend such that a distal end thereof is vertically aligned with an upper end of the inclined wall 222a. The inner wall 226 may extend vertically from an inner end of the bottom wall 224 in an upward direction. The inner wall 226 may extend to a position where an upper end thereof is spaced, by a certain distance, from the upper end of the inclined wall 222a. A spacing in a vertical direction between the inner wall 226 and the inclined wall 222a may function as the inlet 227 of the inner collection container 220 as described above.

A plurality of openings 223 may be formed in the inner wall 226 and may be arranged in a ring arrangement. Each of the openings 223 may be provided in a slit shape. The opening 223 may function as a discharge hole through which the gases introduced into the inner collection container 220 are discharged out thereof through a lower space within the spin chuck device 40. A discharge pipe 225 may be coupled to the bottom wall 224. The treatment liquid introduced into the inner collection container 220 may be discharged to an external chemical regeneration system through the discharge pipe 225.

The guide wall 228 may have an inclined wall 228a that extends inclinedly downwardly from an upper end of the inner wall 226 so as to extend away from the spin chuck device 40 and a vertical wall 228b that vertically extends downwardly from a lower end of the inclined wall 228a. A lower end of the vertical wall 228b may be spaced, by a certain distance, from the bottom wall 224. The guide wall 228 may guide the treatment liquid introduced through the inlet 227 to smoothly flow into a space 229 surrounded with the outer wall 222, the bottom wall 224, and the inner wall 226.

The middle collection container 240 has an outer wall 242, a bottom wall 244, an inner wall 246, and a protruding wall 248. The outer wall 242, the bottom wall 244, and the inner wall 246 of the middle collection container 240 have substantially similar shapes to those of the outer wall 222, the bottom wall 224, and the inner wall 226 of the inner collection container 220, respectively. However, the middle collection container 240 has a larger size than that of the inner collection container 220 so as to surround the inner collection container 220. An upper end of the inclined wall 242a of the outer wall 242 of the middle collection container 240 and the upper end of the inclined wall 222a of the outer wall 222 of the inner collection container 220 are spaced, by a certain distance, from each other in the vertical direction. The spacing therebetween functions as the inlet 247 of the middle collection container 240. The protruding wall 248 extends vertically from a distal end of the bottom wall 244 in a downward direction. An upper end of the inner wall 246 of the middle collection container 240 is in contact with a distal end of the bottom wall 224 of the inner collection container 220. Slit-shaped discharge holes 243 for discharging the gas may be defined in the inner wall 246 of the middle collection container 240 and may be arranged in a ring arrangement. A discharge pipe 245 is coupled to the bottom wall 244. The treatment liquid introduced through the middle collection container 240 may be discharged through the discharge pipe 245 to the external chemical regeneration system.

The outer collection container 260 has an outer wall 262 and a bottom wall 264. The outer wall 262 of the outer collection container 260 has a shape similar to that of the outer wall 242 of the middle collection container 240. The outer collection container 260 has a larger size than that of the middle collection container 240 so that the outer collection container 260 surrounds the middle collection container 240. An upper end of the inclined wall 262a of the outer wall 262 of the outer collection container 260 and the upper end of the inclined wall 242a of the outer wall 242 of the middle collection container 240 are spaced, by a certain distance, from each other in the vertical direction. The spacing therebetween functions as the inlet 267 of the outer collection container 260. The bottom wall 264 has a generally disk shape, and an opening into which the rotatable shaft 42 is inserted is formed in a center of the bottom wall 264. A discharge pipe 265 is coupled to the bottom wall 264. The treatment liquid introduced through the outer collection container 260 may be discharged through the discharge pipe 265 to the external chemical regeneration system. The outer collection container 260 functions as an outer wall of an entirety of the container 20. An exhaust pipe 263 is coupled to the bottom wall 264 of the outer collection container 260, and the gas introduced into the outer collection container 260 is exhausted out thereof through the exhaust pipe 263. Furthermore, the gas flowing out through the discharge hole 223 provided in the inner wall 226 of the inner collection container 220 and the discharge hole 243 provided in the inner wall 246 of the middle collection container 240 may be exhausted to the outside through the exhaust pipe 263 connected to the outer collection container 260. The exhaust pipe 263 may be installed so as to protrude upwardly from the bottom wall 264 by a certain dimension.

The lift unit 30 may linearly move the container 20 in the vertical direction. As the container 20 moves up and down, a relative vertical level of the container 20 to the spin chuck device 40 may change. The lift unit 30 may have a bracket 32, a movable shaft 34, and a driver 36. The bracket 32 may be fixedly installed on the outer wall of the container 20. The movable shaft 34 which moves vertically under an operation of the driver 36 may be fixedly coupled to the bracket 32. When the substrate W is placed on the spin chuck device 40 or lifted up from the spin chuck device 40, the container 20 may be lowered down so that the spin chuck device 40 protrudes upwardly out of a top of the container 20. Furthermore, while the process is in progress, a vertical level of the container 20 may be adjusted so that the treatment liquid flows into a preset one of the collection containers 220, 240, and 260 according to a type of the treatment liquid supplied to the substrate W. Alternatively, the lift unit 30 may move the spin chuck device 40 in the vertical direction.

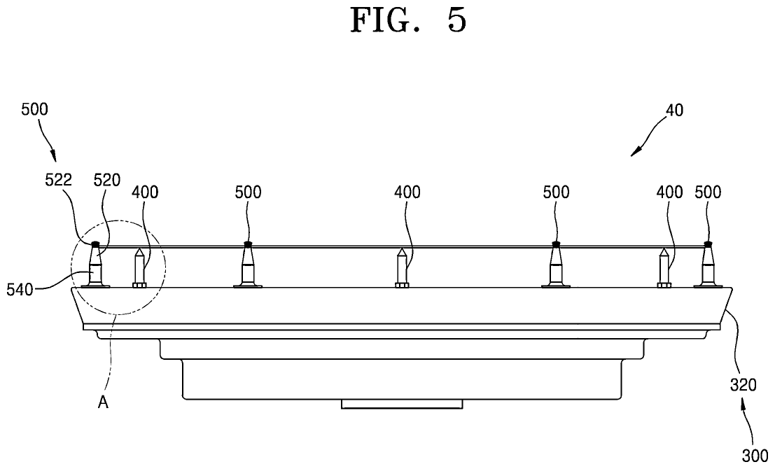

FIG. 4 is a plan view showing the spin chuck device 40 of the substrate processing apparatus 1 in FIG. 1. FIG. 5 is a side elevation view showing the spin chuck device 40 of the substrate processing apparatus 1 of FIG. 4.

As shown in FIGS. 4 and 5, the spin chuck device 40 may include a body 300 constructed to spin-rotate, a plurality of support pins 400 installed on the body 300 so as to support the substrate W, and a plurality of chuck pins 500 installed on the body 300 so as to grip a side surface of the substrate W.

The support pin 400 may support an edge of a back surface of the substrate W so that the substrate W is spaced, by a certain distance, from an upper surface of the body 300. About six support pins 400 may be provided, and all thereof may have the same shape and size. The support pin 400 may have an upper portion whose a diameter gradually increases as the upper portion extends downwards, and a lower portion whose a diameter is constant as the lower portion extends downwards. All of the support pins 400 may have the same protruding height so as to evenly support the substrate W when the substrate W is seated thereon.

The chuck pin 500 may be installed on the body 300 at an edge of the body 300 so as to protrude upwardly from the upper surface of the body 300. The chuck pin 500 may be installed between the adjacent support pins 400, and about six chuck pins 500 may be provided. Thus, the number of chuck pins 500 may be equal to the number of support pins 400. The chuck pins 500 may support the side surface of the substrate W so that the substrate W does not escape from its correct position in a lateral direction when the spin chuck device 40 spin-rotates.

As shown in FIG. 4, FIG. 5 and FIG. 12, all of the chuck pins 500 may have the same shape and size. Each of the chuck pins 500 has a supporting portion 520, a middle portion 540, a fastening portion 560, and a supported portion 580. The supporting portion 520 has a shape in which a diameter thereof gradually decreases and then gradually increases as the supporting portion 520 extends downwardly from a flat upper surface thereof. Therefore, the supporting portion 520 has a concave portion 522 concave inwardly in a front view. The concave portion 522 may come into contact with the side surface of the substrate W placed on the support pin 400. The middle portion 540 may extend downwards from a lower end of the supporting portion 520 while having the same diameter as that of the lower end. The fastening portion 560 may extend downwards from the middle portion 540. A screw hole for fastening the chuck pin to the chuck pin driver device 600 may be formed in the fastening portion 560. The supported portion 580 extends outwardly from the middle portion 540 and may extend in a ring shape. The supported portion 580 is in close contact with the upper surface of the body 300, and all of the chuck pins 500 may have the same protruding height.

The body 300 may include an upper plate 320 and a lower plate 340. The upper plate 320 has an upper surface provided in a generally circular shape in a top view. The lower plate 340 is disposed under the upper plate 320 and may provide a space in which the chuck pin driver device 600 is disposed.

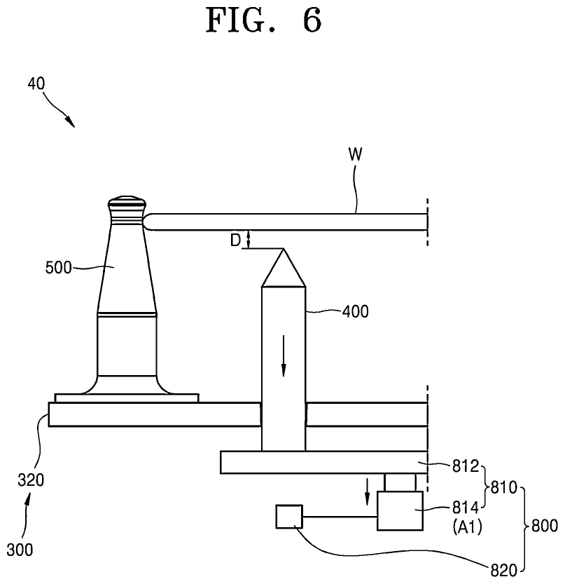

FIG. 6 is a conceptual diagram showing an example of a support pin elevating and lowering device 810 of the spin chuck device 40 in FIG. 5.

As shown in FIGS. 1 to 6, the spin chuck device 40 of the substrate processing apparatus 1 according to some embodiments of the present disclosure may further include a support pin spacing device 800 configured to space the substrate W and at least one support pin 400 from each other by a spacing D so as to prevent process non-uniformity from occurring due to a contact portion between the substrate W and the support pin 400 while the chuck pin 500 grips the substrate W, that is, while the process is in progress.

As shown in FIG. 6, the support pin spacing device 800 may include the support pin elevating and lowering device 810 configured to elevate or lower all the support pins 400 or some of the support pins 400 so that a vertical level of a top of each of the support pins 400 may be lower than that of a top of each of the chuck pins 500. The support pin spacing device 800 may further include a controller 820 configured to apply a lowering control signal to the support pin elevating and lowering device 810 based on a type of the process.

More specifically, for example, the support pin elevating and lowering device 810 may include a support pin moving table 812 supporting and moving at least one support pin 400 so as to elevate or lower at least one support pin 400 through the upper plate 320 of the body 300. The support pin elevating and lowering device 810 may further include a support pin elevating and lowering driver device 814 for elevating and lowering the support pin moving table 812.

For example, as shown in FIG. 6, the support pin moving table 812 may be embodied as a support pin moving plate supporting the plurality of support pins 400 thereon. The support pin elevating and lowering driver device 814 may be embodied as a support pin moving plate cylinder or a support pin moving plate actuator A1 for elevating and lowering the support pin moving plate.

For example, the support pin moving plate cylinder may include all kinds of pneumatic or hydraulic fluid cylinders that elevate and lower the support pin moving plate via a pressure of a working medium. The support pin moving plate actuator A1 may include various types of power transmission devices or drivers such as a combination of various gears, a combination of a moving table and a threaded rod, a combination of a belt and a pulley, a combination of a chain and a sprocket wheel, a combination of a wire and a pulley, a motor, a linear motor, etc.

Therefore, as shown in FIG. 6, when the chuck pin 500 grips the substrate W, the support pin elevating and lowering device 810 may lower all support pins 400 relative to chuck pin 500. Alternatively, when the chuck pin 500 grips the substrate W, the support pin elevating and lowering device 810 may bring at least one support pin 400 to contact the substrate W, and lower at least one further support pin 400, relative to the chuck pin 500.

More specifically, for example, as shown in FIG. 4, in a top view of the body 300, a total of six chuck pins 500 are respectively positioned at 2 o'clock, 4 o'clock, 6 o'clock, 8 o'clock, 10 o'clock, and 12 o'clock positions. Each of a total of six support pins 400 is positioned between adjacent ones of six chuck pins 500, that is, the six support pins 400 are respectively positioned at 1 o'clock, 3 o'clock, 5 o'clock, 7 o'clock, 9 o'clock, and 11 o'clock positions. In this case, the support pin elevating and lowering device 810 may bring only three support pins 400 triangularly arranged at the 3 o'clock, 7 o'clock and 11 o'clock positions to be in contact with the substrate W, and may lower the remaining three support pins 400 triangularly arranged at the 1 o'clock, 5 o'clock, and 9 o'clock positions so as to be spaced from the substrate W by the spacing.

In this regard, the elevating and lowering operation of the support pins 400 is not necessarily limited thereto. A wide variety of combinations and numbers of the support pins 400 may be elevated or lowered.

Therefore, some of the support pins 400 together with the chuck pins 500 spin-rotate the substrate W stably, while the remaining support pins 400 is relatively spaced from the substrate W by the spacing D, such that the process uniformity of the back side of the substrate W may be greatly improved. As a result, a subsequent process may proceed smoothly, and high-quality products with high yield and reliability may be produced.

In addition, the support pins 400 in contact with the substrate W and the support pins 400 spaced from the substrate W may not be pre-determined. Rather, each of all the support pins 400 may be spaced from the substrate W at each of different timings.

That is, in a top view of the body 300, a total of six chuck pins 500 are respectively positioned at 2 o'clock, 4 o'clock, 6 o'clock, 8 o'clock, 10 o'clock, and 12 o'clock positions. Each of a total of six support pins 400 is positioned between adjacent ones of six chuck pins 500, that is, the six support pins 400 are respectively positioned at 1 o'clock, 3 o'clock, 5 o'clock, 7 o'clock, 9 o'clock, and 11 o'clock positions. In this case, for a first process time, first, the support pin elevating and lowering device 810 may bring only three support pins 400 triangularly arranged at the 3 o'clock, 7 o'clock and 11 o'clock positions to be in contact with the substrate W, and may lower the remaining three support pins 400 triangularly arranged at the 1 o'clock, 5 o'clock, and 9 o'clock positions so as to be spaced from the substrate W by the spacing.

Then, for a second process time, second, the support pin elevating and lowering device 810 may bring only the three support pins 400 triangularly arranged at the 1 o'clock, 5 o'clock, and 9 o'clock positions and may lower the remaining three support pins 400 triangularly arranged at the 3 o'clock, 7 o'clock and 11 o'clock positions so as to be spaced from the substrate W by the spacing. In this way, each of all of the support pins 400 may alternately contact and be spaced from the substrate W in a repeated manner.

Therefore, while the substrate W and each of all the support pins 400 repeatedly and alternately contact each other and are spaced from each other during the process, the uniformity of the process on the back side of substrate W may be greatly improved, and as a result, the subsequent process may proceed smoothly, and high-quality products with high yield and reliability may be obtained.

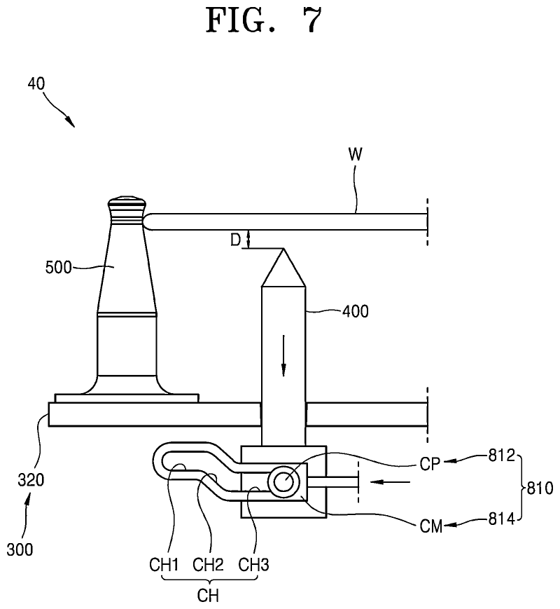

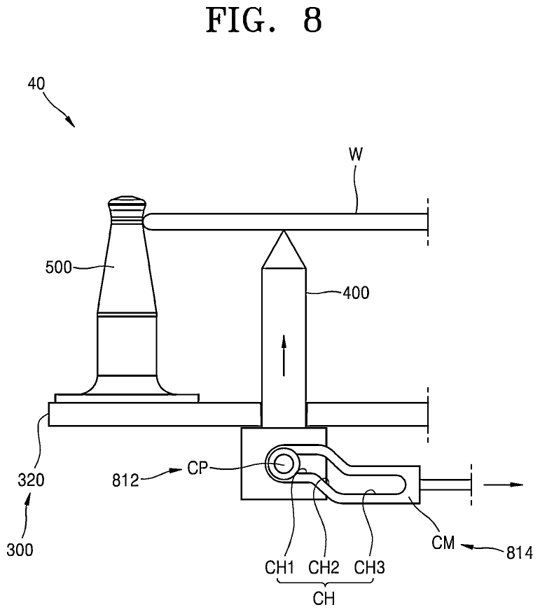

FIG. 7 is a cross-sectional view showing the support pin lowered state according to another example of the support pin elevating and lowering device 810 of the spin chuck device 40 of FIG. 5. FIG. 8 is a cross-sectional view showing the support pin elevated state of the support pin elevating and lowering device 810 of the spin chuck device 40 in FIG. 7.

As shown in FIG. 7 and FIG. 8, in one example of the support pin elevating and lowering device 810 of the spin chuck device 40 of the present disclosure, the support pin moving table 812 may be embodied as an elevating and lowering cam pin CP disposed at a lower end of the support pin 400 and protruding therefrom outwardly. The support pin elevating and lowering driver device 814 may be embodied as an elevating and lowering cam member CM having a cam hole CH defined therein and extending in a bent manner, wherein at least a portion of the elevating and lowering cam pin CP is inserted into the cam hole CH such that the elevating and lowering cam member CM induces an elevating and lowering motion of the elevating and lowering cam pin CP.

More specifically, for example, the cam hole CH may be composed of a cam hole upper area CH1 which guides the elevating and lowering cam pin CP disposed at the lower end of the support pin 400 and protruding therefrom outwardly so as to move upwardly, a cam hole inclined area CH2, that guides the elevating and lowering cam pin CP to move in an inclined manner, and a cam hole lower area CH3 that guides the elevating and lowering cam pin CP to move downwardly.

Therefore, as shown in FIG. 7, during the process, the elevating and lowering cam member CM is displaced to the left side as a whole such that the cam hole lower area CH3 guides the elevating and lowering cam pin CP so as to move downwardly, thereby spacing the support pin 400 from the substrate W by the spacing D.

Furthermore, as shown in FIG. 8, in loading or unloading the substrate, the elevating and lowering cam member CM is displaced to the right side as a whole such that the cam hole upper area CH1 extending from the cam hole inclined area CH2 may guide the elevating and lowering cam pin CP to move upwardly. As a result, the substrate W may be stably seated on the support pin 400 or the chuck pin 500 may firmly grip the substrate W seated on the support pin 400.

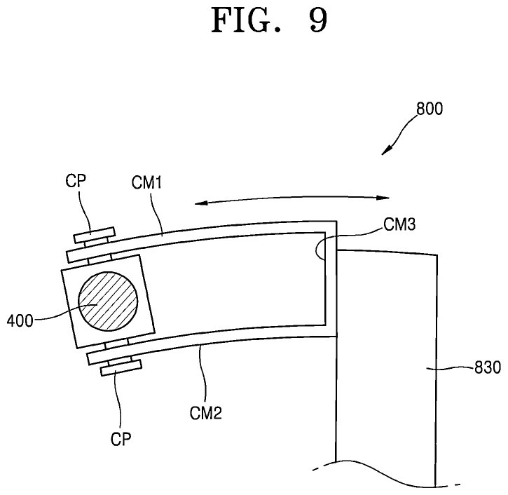

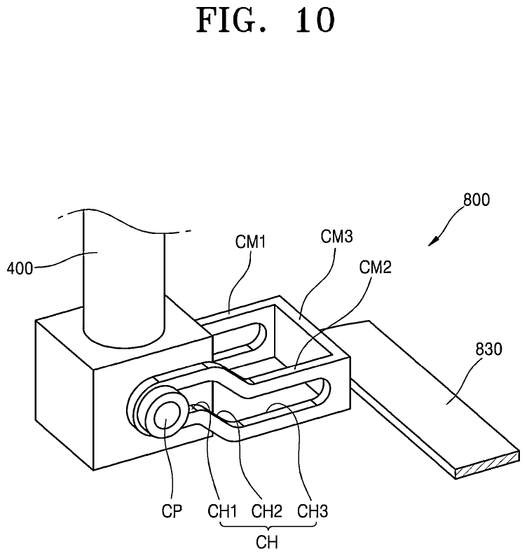

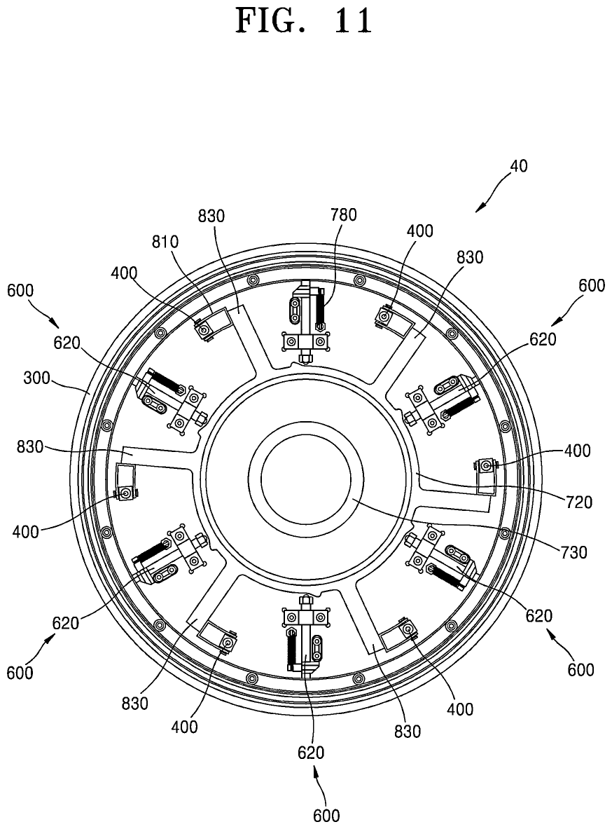

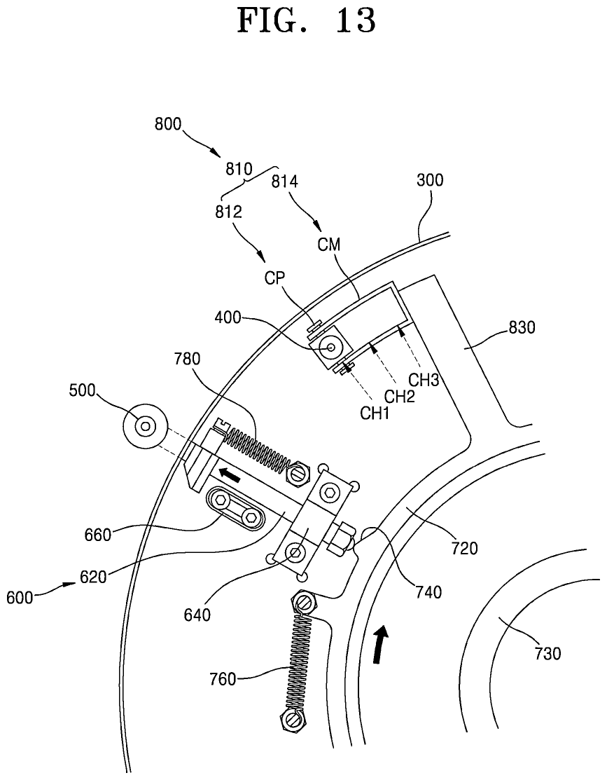

FIG. 9 is a plan view showing the support pin elevating and lowering device 810 of the spin chuck device 40 in FIG. 8. FIG. 10 is a perspective view showing the support pin elevating and lowering device 810 of the spin chuck device 40 in FIG. 9. FIG. 11 is a plan view showing the spin chuck device 40 in FIG. 9, and FIGS. 12 and 13 are cross-sectional views showing the spin chuck device 40 in FIG. 11.

More specifically, for example, as shown in FIGS. 9 to 13, the elevating and lowering cam member CM may be associated with a chuck pin driver device 600 to be described later that drives the chuck pin 500.

The elevating and lowering cam member CM may include an outer cam portion CM1 in which the cam hole CH receiving therein the elevating and lowering cam pin CP disposed at the lower end of the support pin 400 and protruding therefrom outwardly is formed, and an inner cam portion CM2 connected to a rear end of the outer cam portion CM1 via a connection portion CM3, wherein the cam hole CH receiving therein the elevating and lowering cam pin CP disposed at the lower end of the support pin 400 and protruding therefrom outwardly is formed in the inner cam portion CM2.

The chuck pin driver device 600 is configured to move the chuck pin 500 from a standby position to a grip position when the substrate W has been seated on the support pin 400. The chuck pin driver device 600 may move in association with the elevating and lowering cam member CM and together therewith.

As shown in FIGS. 11 and 13, the chuck pin driver device 600 includes a movable rod 620 connected to the chuck pin 500 and linearly displaced by a linear movement guide 640, an elastic member 780 providing an elastic restoring force in a direction in which the movable rod 620 moves in a forward direction, and a rotatable cam member 720 having a protrusion 740 facing the movable rod 620 and capable of pressing the movable rod 620 so as to move the movable rod 620 backwards based on a rotation angle by which the rotatable cam member 720 is rotated by the cam driver 730, wherein the protrusion 740 is formed on one side of an outer circumferential surface of the rotatable cam member 720.

In this regard, the elevating and lowering cam member CM may be installed on an extension 830 formed on the other side of an outer circumference of the rotatable cam member 720 and thus may be associated with the chuck pin driver device 600 so as to elevate and lower the elevating and lowering cam pin CP according to the rotation angle by which the rotatable cam member 720 rotates.

Furthermore, for example, each of the outer cam portion CM1 and the inner cam portion CM2 may be generally formed in a partial arc shape such that a spacing between each of the outer cam portion CM1 and the inner cam portion CM2 and the outer circumferential surface of the rotatable cam member 720 is constant along the outer circumferential surface or a rotation path thereof.

The extension 830 is connected to the connection portion CM3, so that when the extension 830 rotates, a rotational force is evenly distributed to the outer cam portion CM1 and the inner cam portion CM2, thereby elevating and lowering the support pin 400 in the vertical direction.

FIGS. 13 to 15 are partially enlarged plan views showing an operation process of the spin chuck device 40 in FIG. 11 step by step.

As shown in FIGS. 13 to 15, the operation process of the spin chuck device 40 according to some embodiments of the present disclosure will be described step by step. First, as shown in FIG. 13, in a substrate seating mode, the rotatable cam member 720 is rotated clockwise by the cam driver 730 so that the protrusion 740 may press the movable rod 620, and the protrusion 740 in contact with the movable rod 620 may overcome the clastic restoring force of the elastic member 780 and thus move the movable rod 620 backwards.

In this regard, when the movable rod 620 moves backwards under the pushing force from the protrusion 740, a spacing between each of the chuck pins 500 connected to the movable rod 620 and the substrate W may increase. At the same time, as the extension 830 connected to the rotatable cam member 720 rotates clockwise, the elevating and lowering cam member CM moves along the clockwise path as a whole so that the cam hole upper area CH1 guides the elevating and lowering cam pin CP to move upwards. As a result, the substrate W may be stably seated on the elevated plurality of support pins 400.

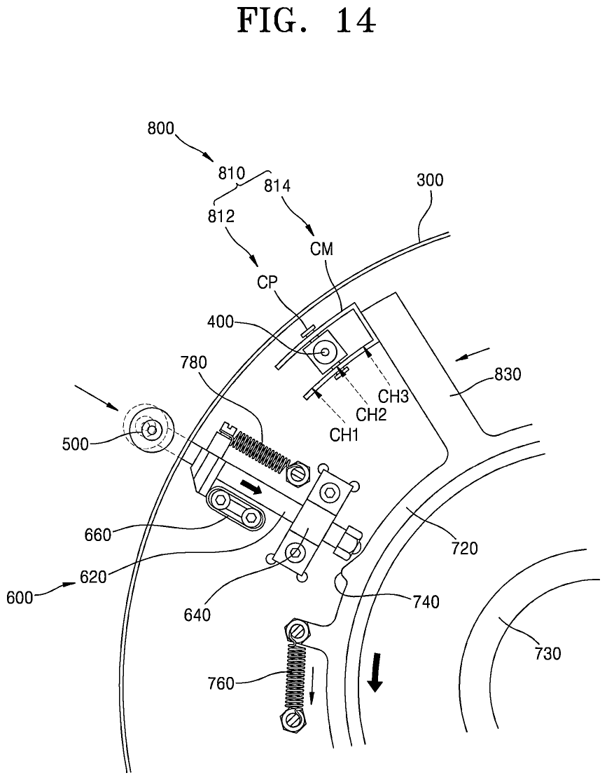

Subsequently, as shown in FIG. 14, in a substrate grip mode, the rotatable cam member 720 is rotated counterclockwise by the cam driver 730 so that the protrusion 740 may be spaced rom the movable rod 620, and thus the movable rod 620 removed from the protrusion 740 may move forwards under the elastic restoring force of the elastic member 780.

In this regard, when the movable rod 620 moves forwards under the elastic restoring force of the elastic member 780, the spacing between each of the chuck pins 500 connected to the movable rod 620 and the substrate W may decrease. Thus, the plurality of chuck pins 500 may firmly grip the side surface of the substrate W seated on the support pins 400.

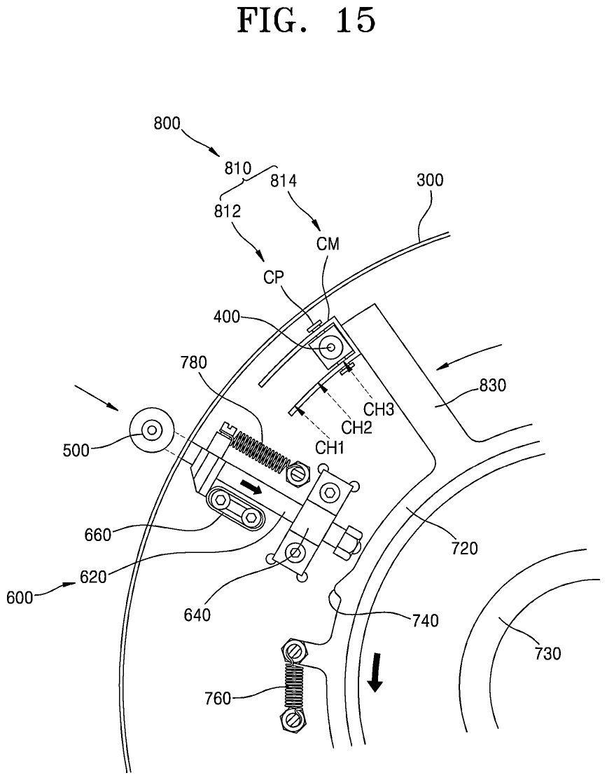

Subsequently, as shown in FIG. 15, in the support pin lowered state, the rotatable cam member 720 is fully rotated counterclockwise by the cam driver 730 such that the extension 830 associated with the rotatable cam member 720 may be fully rotated counterclockwise. As a result, the elevating and lowering cam member CM is fully displaced along an overall counterclockwise path, so that the cam hole lower area CH3 may guide the elevating and lowering cam pin CP guided by the cam hole inclined area CH2 to move downwardly. As a result, the support pin 400 may be spaced from the substrate W by the spacing D.

In this regard, the support pin elevating and lowering device 810 may be installed for each of all of the support pin 400 to lower all support pins 400, or may be selectively installed for each of only some support pins 400 to lower only specific support pins 400.

Furthermore, as shown in FIG. 7 to FIG. 15, an example of the cam hole CH in which the cam hole upper area CH1 is positioned at a left side, the cam hole inclined area CH2 is positioned at a middle side, and the cam hole lower area CH3 is positioned at a right side is illustrated. However, the present disclosure is not limited thereto. An order in which the cam hole upper area CH1, the cam hole inclined area CH2, and the cam hole lower area CH3 may be arranged may vary based on each of the support pins 400. Thus, various elevating and lowering movements may be achieved in association with the rotatable cam member 720.

Therefore, when using the elevating and lowering cam member CM and the cam hole CH, various elevating and lowering operations may be performed, for example, all support pins 400 may be lowered at the same time, or only some thereof may be lowered, or the support pins 400 may be alternately and repeatedly elevated and lowered, depending on locations of the elevating and lowering cam member CM and the cam hole CH, and whether or not they are installed, and a manner in which they are installed.

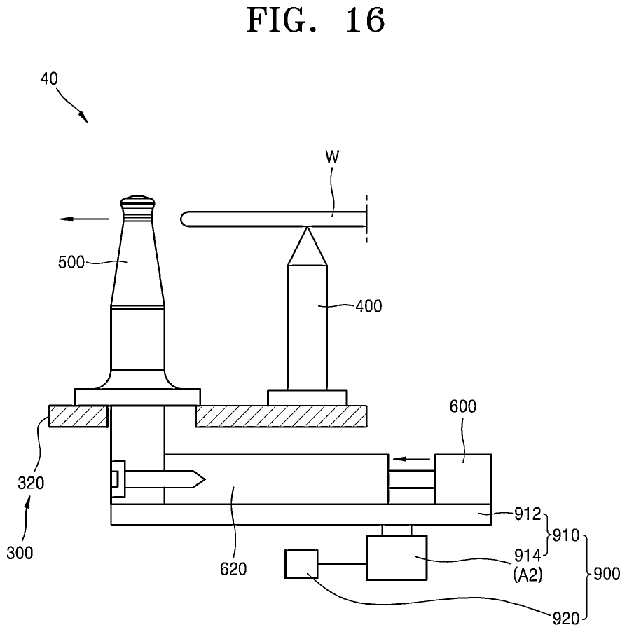

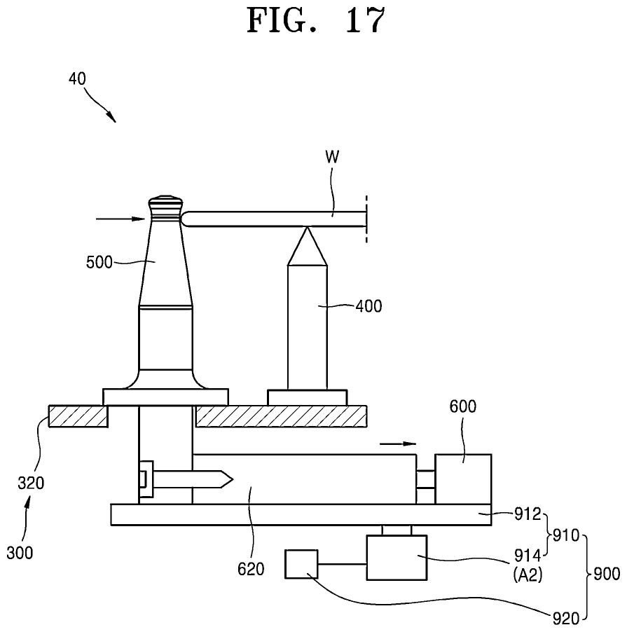

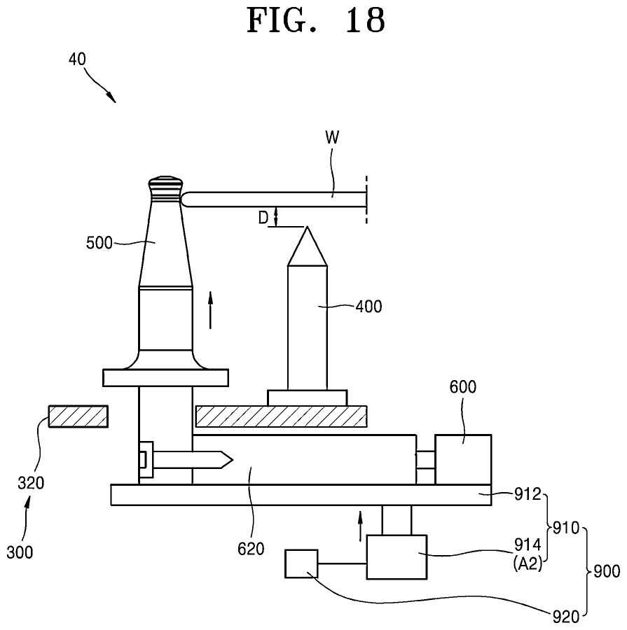

FIG. 16 is a conceptual diagram showing the substrate seated state according to another example of a chuck pin elevating and lowering device 910 of the spin chuck device 40 of FIG. 5. FIG. 17 is a conceptual diagram showing the substrate grip state according to the chuck pin elevating and lowering device 910 of the spin chuck device 40 in FIG. 16. FIG. 18 is a conceptual diagram showing the substrate elevated state according to the chuck pin elevating and lowering device 910 of the spin chuck device 40 in FIG. 17.

As shown in FIGS. 16 to 18, a support pin spacing device 900 of the spin chuck device 40 according to some further embodiments of the present disclosure may include the chuck pin elevating and lowering device 910 which elevates and lowers the chuck pin 500 so that a vertical level of a top of the chuck pin 500 is higher than a vertical level of a top of the support pin 400, and a controller 920 that applies an elevating control signal to the chuck pin elevating and lowering device 910, based on the type of the process.

The chuck pin elevating and lowering device 910 may include a chuck pin moving table 912 supporting and moving the plurality of chuck pins 500 so as to elevate and lower the plurality of chuck pins 500 through the upper plate 320 of the body 300. The chuck pin elevating and lowering device 910 may further include a chuck pin elevating and lowering driver device 914 for elevating and lowering the chuck pin moving table 912.

More specifically, for example, the chuck pin moving table 912 may be embodied as a chuck pin moving plate that supports the plurality of chuck pins 500. The chuck pin elevating and lowering driver device 914 may be embodied as a chuck pin moving plate cylinder or a chuck pin moving plate actuator A2 for elevating and lowering the chuck pin moving plate.

For example, the chuck pin moving plate cylinder may include all kinds of pneumatic or hydraulic fluid cylinders that elevate and lower the chuck pin moving plate via the pressure of the working medium. The chuck pin moving plate actuator A2 may include various types of power transmission devices or drivers such as a combination of various gears, a combination of a moving table and a threaded rod, a combination of a belt and a pulley, a combination of a chain and a sprocket wheel, a combination of a wire and a pulley, a motor, a linear motor, etc.

Therefore, as shown in FIG. 16, when the substrate W is seated on the support pin 400 while the chuck pin 500 has been retracted, the chuck pin 500 may grip the substrate W, as shown in FIG. 17. As shown in FIG. 18, the chuck pin elevating and lowering device 910 elevates all the chuck pins 500 upwardly beyond the support pins 400 so that the substrate W and the support pin 400 may be spaced from each other by the spacing D.

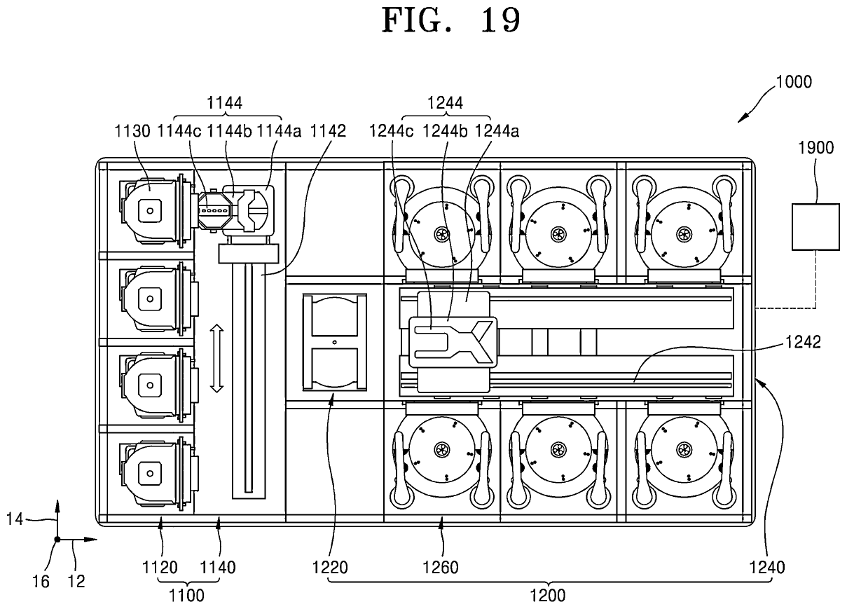

FIG. 19 is a plan view showing a substrate processing facility 1000 including the substrate processing apparatus 1 in which the chuck spin device 40 of FIGS. 1 to 18 is installed.

As shown in FIG. 19, the substrate processing facility 1000 according to some embodiments of the present disclosure performs a process of processing the substrate by supplying the treatment liquid to the substrate. The substrate processing facility 1000 may include a first load port 1120 and a first transfer frame 1140. The first load port 1120, the first transfer frame 1140, and a first process processing module 1200 may be sequentially arranged in a line.

Hereinafter, a direction in which the first load port 1120, the first transfer frame 1140, and the first process processing module 1200 are arranged is referred to as a first direction 12. In a top view, a direction perpendicular to the first direction 12 is referred to as a second direction 14, and a direction perpendicular to a plane including the first direction 12 and the second direction 14 is referred to as a third direction 16.

A first carrier 1130 containing a substrate such as a wafer may be seated in the first load port 1120. A plurality of first load ports 1120 may be provided, and may be arranged in a line along the second direction 14.

Although FIG. 19 shows that four first load ports 1120 are provided, the number of first load ports 1120 may increase or decrease depending on conditions such as process efficiency and footprint of the first process processing module 1200. A slot (not shown) may be formed in the first carrier 1130 so as to support an edge of the substrate.

A plurality of slots may be provided and may be arranged in the third direction 16, and the substrates may be positioned in the first carrier 1130 while being stacked along the third direction 16 in a spaced state from each other. The first carrier 1130 may include FOUP (Front Opening Unified Pod).

The first process processing module 1200 may include a first buffer unit 1220, a first transporting unit 1240, and a first process chamber 1260. A length direction of the first transporting unit 1240 may extend in parallel to the first direction 12. The first process chambers 1260 may be disposed on two opposing sides along the second direction 14 of the first transporting unit 1240, respectively. The first process chambers 1260 located on one side of the first transporting unit 1240 and the first process chambers 1260 located on the other side of the first transporting unit 1240 may be symmetrical with respect to each other around the first transporting unit 1240. Some of the first process chambers 1260 may be arranged along the length direction of the first transporting unit 1240. Furthermore, some of the first process chamber 1260 may be stacked on top of each other. That is, on one side of the first transporting unit 1240, the first process chambers 1260 may be arranged in an array of n rows and m columns, where each of n and m is a natural number. In this regard, n may be the number of first process chambers 1260 arranged in a line along the first direction 12, and m may be the number of first process chambers 1260 arranged in a line along the third direction 16. When four or six first process chambers 1260 are provided on one side of the first transporting unit 1240, the first process chambers 1260 may be arranged in a 2×2 or 3×2 arrangement. The number of first process chambers 1260 may increase or decrease. Unlike what is described above, the process chamber 1260 may be provided only on one side of the first transporting unit 1240. Furthermore, unlike what is described above, the first process chambers 1260 provided on one side or both opposing sides of the first transporting unit 1240 may constitute a single layer.

The first buffer unit 1220 may be disposed between the first transfer frame 1140 and the first transporting unit 1240. The first buffer unit 1220 may provide a space in which the substrate may stay before the substrate is transported between the first transporting unit 1240 and the first transfer frame 1140. The first buffer unit 1220 may have a slot (not shown) defined therein in which the substrate is placed. A plurality of slots may be arranged so as to be spaced apart from each other along the third direction 16. A surface of the first buffer unit 1220 facing the first transfer frame 1140 and a surface thereof facing the first transporting unit 1240 may be opened.

The first transfer frame 1140 may transport a substrate between the first carrier 1130 seated in the first load port 1120 and the first buffer unit 1220. A first index rail 1142 and a first index robot 1144 may be provided on the first transfer frame 1140. A length direction of the first index rail 1142 may be parallel to the second direction 14. The first index robot 1144 may be installed on the first index rail 1142 and may linearly move in the second direction 14 along the first index rail 1142. The first index robot 1144 may include a first base 1144a, a first body 1144b, and a first index arm 1144c. The first base 1144a may be installed to be movable along the first index rail 1142. The first body 1144b may be coupled to the first base 1144a. The first body 1144b may be disposed on the first base 1144a and may be configured to be movable along the third direction 16. Furthermore, the first body 1144b may be disposed on the first base 1144a and may be configured to be rotatable. The first index arm 1144c may be coupled to the first body 1144b and may be configured to move forward and backward with respect to the first body 1144b. A plurality of first index arms 1144c may be provided and may individually operate. The first index arms 1144c are stacked in a relatively spaced state from each other along the third direction 16. Some of the first index arms 1144c may be used to transport the substrate from the first process processing module 1200 to the first carrier 1130, and the others thereof may be used to transport the substrate from the first carrier 1130 to the first process processing module 1200. This may prevent particles generated from the substrate before process processing thereon from being attached to the substrate after the process processing in a process of carrying in and out of the substrate using the first index robot 1144.

The first transporting unit 1240 may transport the substrate W between the first buffer unit 1220 and the first process chamber 1260 and between the first process chambers 1260. A first guide rail 1242 and a first main robot 1244 may be provided on the first transporting unit 1240. The first guide rail 1242 may extend so that its longitudinal direction is parallel to the first direction 12. The first main robot 1244 may be installed on the first guide rail 1242 and may move linearly along the first direction 12 on the first guide rail 1242. The first main robot 1244 may include a first base 1244a, a first body 1244b, and a first main arm 1244c. The first base 1244a may be installed to be movable along the first guide rail 1242. The first body 1244b may be coupled to the first base 1244a. The first body 1244b may be disposed on the first base 1244a and may be configured to be movable along the third direction 16. Furthermore, the first body 1244b may be disposed on the first base 1244a and may be configured to be rotatable. The first main arm 1244c may be coupled to the first body 1244b, and may be configured to move forward and backward with respect to the first body 1244b. A plurality of first main arms 1244c may be provided and may be configured to individually operate. The first main arms 1244c may be stacked in a relatively spaced state from each other along the third direction 16. The first main arm 1244c used to transfer the substrate from the first buffer unit 1220 to the first process chamber 1260, and the first main arm 1244c used to transfer the substrate from the first process chamber 1260 to the first buffer unit 1220 may differ from each other.

An inside of the first process chamber 1260 may be configured to perform a cleaning process on the substrate. The first process chambers 1260 may have different structures depending on types of the cleaning process. Alternatively, the first process chambers 1260 may have the same structure. Alternatively, the first process chambers 1260 may be divided into a plurality of groups, so that the first process chambers 1260 belonging to the same group may have the same structure, while the first process chambers 1260 belonging to different groups may have different structures. For example, when the first process chambers 1260 is divided into two groups, the first process chambers 1260 of the first group may be provided on one side of the first transporting unit 1240, while the first process chambers 1260 of the second group may be provided on the other side of the first transporting unit 1240. Alternatively, on each of one side and the other side of the first transporting unit 1240, the first process chambers 1260 of the first group may be provided in a lower layer, while the first process chambers 1260 of the second group may be provided in an upper layer. The first process chamber 1260 of the first group and the first process chamber 1260 of the second group may be distinguished from each other based on the type of the chemical as used or the type of the cleaning scheme. The first process chamber 1260 may be provided with the substrate processing apparatus 1 as described above.

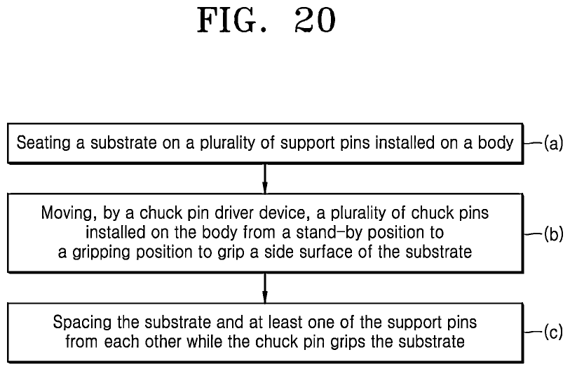

FIG. 20 is a flowchart illustrating a substrate processing method according to some embodiments of the present disclosure.

As shown in FIGS. 1 to 20, the substrate processing method according to some embodiments of the present disclosure includes (a) seating the substrate W on the plurality of support pins 400 installed on the body 300; (b) moving, by the chuck pin driver device 600, the plurality of chuck pins 500 installed on the body 300 from a stand-by position to a gripping position to grip the side surface of the substrate W; and (c) while the chuck pin 500 grips the substrate W, that is, while the process is in progress, spacing at least one of the support pins 400 from the substrate Win order to prevent the process non-uniformity from occurring due to the contact between the substrate W and the support pin 400.

Furthermore, for example, in the (c), at least one support pin 400 may be lowered based on the chuck pin 500 using the support pin elevating and lowering device 810, or the chuck pin 500 may be elevated based on the support pin 400 using the chuck pin elevating and lowering device 910.

Furthermore, for example, the (c) may be applied to various processes. For example, the (c) includes spacing the substrate W and the at least one of the support pins 400 from each other using the support pin elevating and lowering device or the chuck pin elevating and lowering device during a process or before the process, wherein the process may be one selected from: a pre-rinse process of rotating the substrate at a first rotation speed while supplying a pre-rinse liquid to the substrate; an initial etching process of rotating the substrate at a second rotation speed while supplying an etchant to a center of the substrate; a middle etching process of rotating the substrate at a third rotation speed while supplying an etchant to the substrate in a scanning manner; a last etching process of stopping the supply of the etchant to the substrate, and rotating the substrate at a fourth rotation speed to remove the etchant remaining on the substrate; a cleaning process of rotating the substrate at a fifth rotation speed while supplying a rinse liquid or cleaning liquid to the substrate so as to clean the substrate; a drying process of supplying a drying gas to the substrate or rotating the substrate at a sixth rotation speed in a dried state thereof; and combinations thereof.

In this regard, the number of support pins 400 to be spaced apart from the substrate W or the position of the support pin 400 to be spaced apart therefrom may be determined based on the rotation speed of the substrate W.

That is, when the substrate W is rotated at a relatively high speed, such as, for example, in the middle etching process, the cleaning process, or the drying process, all the support pins 400 may be in contact with the substrate W, or only a small number of support pins 400 or the support pins 400 at unnecessary positions other than triangular arrangement for supporting the substrate may be spaced from the substrate W, in order to cope with a large centrifugal force and to more firmly support the substrate W.

On the contrary, when the substrate W is rotated at a relatively low speed, such as, for example, in the pre-rinse process, the initial etching process, or the last etching process, all the support pins 400 may be spaced from the substrate W, or a large number of support pins 400 other than a minimum number of support pins 400 may be spaced from the substrate W, in order to prevent the processing non-uniformity of the substrate W as much as possible.

Further, the (c) may include: when in a top view of the body 300, the chuck pins 500 are respectively positioned at 2 o'clock, 4 o'clock, 6 o'clock, 8 o'clock, 10 o'clock, and 12 o'clock positions, and the support pins 400 are respectively positioned at 1 o'clock, 3 o'clock, 5 o'clock, 7 o'clock, 9 o'clock, and 11 o'clock positions, brining, by the support pin elevating and lowering device 810, the support pins 400 respectively positioned at the 3 o'clock, 7 o'clock and 11 o'clock positions into contact with the substrate W, and lowering, by the support pin elevating and lowering device 810, the support pins 400 respectively positioned at the 1 o'clock, 5 o'clock, and 9 o'clock positions so as to be spaced from the substrate; or for a first process time, bringing, by the support pin elevating and lowering device 810, the support pins 400 respectively positioned at the 3 o'clock, 7 o'clock and 11 o'clock positions into contact with the substrate, and lowering, by the support pin elevating and lowering device 810, the support pins 400 respectively positioned at the 1 o'clock, 5 o'clock, and 9 o'clock positions so as to be spaced from the substrate; and then, for a second process time, bringing, by the support pin elevating and lowering device 810, the support pins 400 respectively positioned at the 1 o'clock, 5 o'clock, and 9 o'clock positions into contact with the substrate, and lowering, by the support pin elevating and lowering device 810, the support pins 400 respectively positioned at the 3 o'clock, 7 o'clock and 11 o'clock positions so as to be spaced from the substrate.

Therefore, during the spin process, the substrate W and the support pin 400 may be spaced from each other by the spacing D by elevating or lowering the support pin 400 or the chuck pin 500. As a result, the processing uniformity of the substrate may be greatly improved. The spacing D may be adjusted to be optimal according to a type of the process, and the vertical levels of the support pin 400 and the chuck pin 500 may be adjusted individually or in association with each other. Depending on the goal and characteristics of the process, the vertical levels of the support pin 400 and the chuck pin 500 may be precisely adjusted based on a position or a time.

Although the present disclosure has been described with reference to the embodiments shown in the drawings, this is only illustrative, and those skilled in the art will understand that various modifications and equivalent other embodiments are possible therefrom. Therefore, the true technical protection scope of the present disclosure should be determined by the technical spirit of the appended claims.

What is claimed is:

1. A substrate processing apparatus comprising:
a body configured to spin-rotate;
a plurality of support pins installed on the body so as to support the substrate thereon;
a plurality of chuck pins installed on the body so as to grip a side surface of the substrate;
a chuck pin driver device configured to move the chuck pin from a stand-by position to a grip position when the substrate has been seated on the support pin; and
a support pin spacing device configured to space the substrate and at least one of the support pins from each other while the chuck pin is gripping the substrate.

2. The substrate processing apparatus of claim 1, wherein the support pin spacing device includes:
a support pin elevating and lowering device configured to lower the at least one support pin such that a vertical level of a top of the at least one support pin is lower than a vertical level of a top of the chuck pin; and
a controller configured to apply a lowering control signal to the support pin elevating and lowering device based on a type of a process.

3. The substrate processing apparatus of claim 2, wherein the support pin elevating and lowering device includes:
a support pin moving table configured to support and move the at least one support pin to elevate or lower the at least one support pin while passing through an upper plate of the body; and
a support pin elevating and lowering driver device configured to elevate and lower the support pin moving table.

4. The substrate processing apparatus of claim 2, wherein when the chuck pin grips the substrate, the support pin elevating and lowering device is configured to lower all the support pins relative to the chuck pin.

5. The substrate processing apparatus of claim 2, wherein when the chuck pin grips the substrate, the support pin elevating and lowering device is configured to bring at least one support pin into contact with the substrate and to lower at least one further support pin relative to the chuck pin.

6. The substrate processing apparatus of claim 5, wherein in a top view of the body, the chuck pins are respectively positioned at 2 o'clock, 4 o'clock, 6 o'clock, 8 o'clock, 10 o'clock, and 12 o'clock positions,
wherein the support pins are respectively positioned at 1 o'clock, 3 o'clock, 5 o'clock, 7 o'clock, 9 o'clock, and 11 o'clock positions,
wherein the support pin elevating and lowering device is configured to bring the support pins respectively positioned at the 3 o'clock, 7 o'clock and 11 o'clock positions into contact with the substrate, and to lower the support pins respectively positioned at the 1 o'clock, 5 o'clock, and 9 o'clock positions so as to be spaced from the substrate.

7. The substrate processing apparatus of claim 5, wherein in a top view of the body, the chuck pins are respectively positioned at 2 o'clock, 4 o'clock, 6 o'clock, 8 o'clock, 10 o'clock, and 12 o'clock positions,
wherein the support pins are respectively positioned at 1 o'clock, 3 o'clock, 5 o'clock, 7 o'clock, 9 o'clock, and 11 o'clock positions,
wherein the support pin elevating and lowering device is configured to:
for a first process time, bring the support pins respectively positioned at the 3 o'clock, 7 o'clock and 11 o'clock positions into contact with the substrate, and to lower the support pins respectively positioned at the 1 o'clock, 5 o'clock, and 9 o'clock positions so as to be spaced from the substrate; and
for a second process time, bring the support pins respectively positioned at the 1 o'clock, 5 o'clock, and 9 o'clock positions into contact with the substrate, and to lower the support pins respectively positioned at the 3 o'clock, 7 o'clock and 11 o'clock positions so as to be spaced from the substrate.

8. The substrate processing apparatus of claim 3, wherein the support pin moving table is embodied as a support pin moving plate for supporting the plurality of the support pins,
wherein the support pin elevating and lowering driver device is embodied as a support pin moving plate cylinder or a support pin moving plate actuator for elevating and lowering the support pin moving plate.

9. The substrate processing apparatus of claim 3, wherein the support pin moving table includes an elevating and lowering cam pin formed at a lower end of the support pin so as to protrude therefrom,
wherein the support pin elevating and lowering driver device includes an elevating and lowering cam member having a cam hole defined therein extending in a bent manner,
wherein at least a portion of the elevating and lowering cam pin is inserted in the cam hole such that the cam hole allows the elevating and lowering cam pin to move upwardly or downwardly.

10. The substrate processing apparatus of claim 9, wherein the chuck pin driver device includes:
a movable rod connected to the chuck pin and linearly displaced by a linear movement guide;
an elastic member providing an elastic restoring force in a direction in which the movable rod moves forwards; and
a rotatable cam member having a protrusion formed on one side of an outer circumferential surface of the rotatable cam member, wherein the protrusion faces the movable rod and is capable of pressing the movable rod so as to move the movable rod backwards, based on a rotation angle by which the rotatable cam member is rotated by a cam driver,
wherein the elevating and lowering cam member is installed on an extension formed on the other side of the outer circumferential surface of the rotatable cam member, and thus is associated with the chuck pin driver device so as to elevate and lower the elevating and lowering cam pin based on the rotation angle by which the rotatable cam member rotates.

11. The substrate processing apparatus of claim 9, wherein the elevating and lowering cam member includes:
an outer cam portion having a cam hole defined therein receiving therein an elevating and lowering cam pin disposed at a lower end of the support pin and protruding therefrom outwardly; and
an inner cam portion connected to a rear end of the outer cam portion via a connection portion, wherein the cam hole receiving therein the elevating and lowering cam pin disposed at the lower end of the support pin and protruding therefrom outwardly is defined in the inner cam portion,
wherein the extension is connected to the connection portion.

12. The substrate processing apparatus of claim 11, wherein each of the outer cam portion and the inner cam portion is generally formed in a partial arc shape such that a spacing between each of the outer cam portion and the inner cam portion and the outer circumferential surface of the rotatable cam member is constant along the outer circumferential surface thereof.

13. The substrate processing apparatus of claim 1, wherein the support pin spacing device includes:
a chuck pin elevating and lowering device configured to elevate the chuck pin relative to the support pin such that a vertical level of a top of the chuck pin is higher than a vertical level of a top of the support pin; and
a controller configured to apply an elevating control signal to the chuck pin elevating and lowering device based on a type of a process.

14. The substrate processing apparatus of claim 13, wherein the chuck pin elevating and lowering device includes:
a chuck pin moving table configured to support and move a plurality of chuck pins to elevate or lower the plurality of chuck pins while passing through an upper plate of the body; and
a chuck pin elevating and lowering driver device configured to elevate or lower the chuck pin moving table.

15. The substrate processing apparatus of claim 14, wherein the chuck pin moving table is embodied as a chuck pin moving plate supporting the plurality of chuck pins,
wherein the chuck pin elevating and lowering driver device is embodied as a chuck pin moving plate cylinder or a chuck pin moving plate actuator configured to elevate or lower the chuck pin moving plate.

16. A substrate processing method comprising:
(a) seating a substrate on a plurality of support pins installed on a body;
(b) moving, by a chuck pin driver device, a plurality of chuck pins installed on the body from a stand-by position to a gripping position to grip a side surface of the substrate; and
(c) spacing the substrate and at least one of the support pins from each other while the chuck pin grips the substrate.

17. The method of claim 16, wherein the (c) includes spacing the substrate and the at least one of the support pins from each other using a support pin elevating and lowering device or a chuck pin elevating and lowering device during a process or before the process,
wherein the process is one selected from:
a pre-rinse process of rotating the substrate at a first rotation speed while supplying a pre-rinse liquid to the substrate;
an initial etching process of rotating the substrate at a second rotation speed while supplying an etchant to a center of the substrate;
a middle etching process of rotating the substrate at a third rotation speed while supplying an etchant to the substrate in a scanning manner;
a last etching process of stopping the supply of the etchant to the substrate, and rotating the substrate at a fourth rotation speed to remove the etchant remaining on the substrate;
a cleaning process of rotating the substrate at a fifth rotation speed while supplying a rinse liquid or cleaning liquid to the substrate so as to clean the substrate;
a drying process of supplying a drying gas to the substrate or rotating the substrate at a sixth rotation speed in a dried state thereof; and
combinations thereof.

18. The method of claim 17, wherein the (c) includes determining a number of the support pins to be spaced from the substrate or a position of the support pin to be spaced from the substrate, based on the rotation speed of the substrate.

19. The method of claim 16, wherein the (c) includes:
when in a top view of the body, the chuck pins are respectively positioned at 2 o'clock, 4 o'clock, 6 o'clock, 8 o'clock, 10 o'clock, and 12 o'clock positions, and the support pins are respectively positioned at 1 o'clock, 3 o'clock, 5 o'clock, 7 o'clock, 9 o'clock, and 11 o'clock positions,
brining, by a support pin elevating and lowering device, the support pins respectively positioned at the 3 o'clock, 7 o'clock and 11 o'clock positions into contact with the substrate, and lowering, by the support pin elevating and lowering device, the support pins respectively positioned at the 1 o'clock, 5 o'clock, and 9 o'clock positions so as to be spaced from the substrate; or
for a first process time, bringing, by the support pin elevating and lowering device, the support pins respectively positioned at the 3 o'clock, 7 o'clock and 11 o'clock positions into contact with the substrate, and lowering, by the support pin elevating and lowering device, the support pins respectively positioned at the 1 o'clock, 5 o'clock, and 9 o'clock positions so as to be spaced from the substrate; and then,
for a second process time, bringing, by the support pin elevating and lowering device, the support pins respectively positioned at the 1 o'clock, 5 o'clock, and 9 o'clock positions into contact with the substrate, and lowering, by the support pin elevating and lowering device, the support pins respectively positioned at the 3 o'clock, 7 o'clock and 11 o'clock positions so as to be spaced from the substrate.

20. A substrate processing apparatus comprising:
a body configured to spin-rotate;
a plurality of support pins installed on the body so as to support the substrate thereon;
a plurality of chuck pins installed on the body so as to grip a side surface of the substrate;
a chuck pin driver device configured to move the chuck pin from a stand-by position to a grip position when the substrate has been seated on the support pin; and
a support pin spacing device configured to space the substrate and at least one of the support pins from each other while the chuck pin is gripping the substrate,
wherein the support pin spacing device includes:
a support pin elevating and lowering device configured to lower the at least one support pin such that a vertical level of a top of the at least one support pin is lower than a vertical level of a top of the chuck pin; and
a controller configured to apply a lowering control signal to the support pin elevating and lowering device based on a type of a process,
wherein the support pin elevating and lowering device includes:
a support pin moving table configured to support and move the at least one support pin to elevate or lower the at least one support pin while passing through an upper plate of the body; and
a support pin elevating and lowering driver device configured to elevate and lower the support pin moving table,
wherein the support pin moving table includes an elevating and lowering cam pin formed at a lower end of the support pin so as to protrude therefrom,
wherein the support pin elevating and lowering driver device includes an elevating and lowering cam member having a cam hole defined therein extending in a bent manner, wherein at least a portion of the elevating and lowering cam pin is inserted in the cam hole such that the cam hole allows the elevating and lowering cam pin to move upwardly or downwardly,
wherein the chuck pin driver device includes:
a movable rod connected to the chuck pin and linearly displaced by a linear movement guide;
an elastic member providing an elastic restoring force in a direction in which the movable rod moves forwards; and
a rotatable cam member having a protrusion formed on one side of an outer circumferential surface of the rotatable cam member, wherein the protrusion faces the movable rod and is capable of pressing the movable rod so as to move the movable rod backwards, based on a rotation angle by which the rotatable cam member is rotated by a cam driver,
wherein the elevating and lowering cam member is installed on an extension formed on the other side of the outer circumferential surface of the rotatable cam member, and thus is associated with the chuck pin driver device so as to elevate and lower the elevating and lowering cam pin based on the rotation angle by which the rotatable cam member rotates,
wherein the elevating and lowering cam member includes:
an outer cam portion having a cam hole defined therein receiving therein an elevating and lowering cam pin disposed at a lower end of the support pin and protruding therefrom outwardly; and
an inner cam portion connected to a rear end of the outer cam portion via a connection portion, wherein the cam hole receiving therein the elevating and lowering cam pin disposed at the lower end of the support pin and protruding therefrom outwardly is defined in the inner cam portion,
wherein the extension is connected to the connection portion,
wherein each of the outer cam portion and the inner cam portion is generally formed in a partial arc shape such that a spacing between each of the outer cam portion and the inner cam portion and the outer circumferential surface of the rotatable cam member is constant along the outer circumferential surface thereof.
